(19) United States
(12) Patent Application Publication
(10) Pub. No.: US 2023/0386264 A1
(43) Pub. Date: Nov. 30, 2023

(54) REPLACEMENT-TIME POSITION IDENTIFICATION SYSTEM AND REPLACEMENT-TIME POSITION IDENTIFICATION METHOD

(71) Applicant: HONDA MOTOR CO., LTD., Tokyo (JP)

(72) Inventors: Kohei MUKAIHARA, Tokyo (JP); Satoshi YOSHIMARU, Tokyo (JP)

(21) Appl. No.: 18/321,715

(22) Filed: May 22, 2023

(30) Foreign Application Priority Data
May 24, 2022 (JP) 2022-084271

(51) Int. Cl. G07C 5/00

(52) U.S. Cl. CPC G07C 5/008; G07C 5/006

(57) ABSTRACT

A replacement-time position identification system of consumable parts includes a consumable part consumption degree grasper that grasps an internal resistance value of a consumable part included in a movable body, a position acquirer that acquires a travel position status in response to an ignition of the movable body being turned on or off, a data receiver that receives data from the consumable part consumption degree grasper and data from the position acquirer, and a replacement-time position acquirer that, based on a travel status of the movable body, when a value of data of the internal resistance value from the consumable part consumption degree grasper satisfies a predetermined requirement in change, identifies a position of the movable body as a replacement position of the consumable part.

This application is based on and claims the benefit of priority from Japanese Patent Application No. 2022-084271, filed on 24 May 2022, the content of which is incorporated herein by reference.

### BACKGROUND OF THE INVENTION

### Field of the Invention

The present invention relates to a replacement-time position identification system of consumable parts and a replacement-time position identification method of consumable parts.

### Related Art

Conventionally, a system has been provided to enable efficient inspection of components of a movable body at the appropriate timing (for example, refer to Japanese Unexamined Patent Application, Publication No. 2003-196378).
Patent Document 1: Japanese Unexamined Patent Application, Publication No. 2003-196378

### SUMMARY OF THE INVENTION

In the conventional system, when a customer of a vehicle as a movable body defects from a dealership and leaves for a competitor company, it is not possible to detect the customer. Therefore, it is not possible to grasp the states of components of a vehicle of such a customer appropriately. That is, if a customer defects from a dealership and replaces the vehicle's components through a competitor company, the customer's vehicle would have no contact with the dealership and no information about the customer would be available. This makes the approach for recapture of a customer to subsequently return to the dealership very difficult. As a result, it is not possible to accurately determine its share of the market, making it extremely difficult to formulate effective sales promotion strategies based on this information and forcing it to rely on the hard work by feel in the field.

An object of the present invention is to, for the purpose of improving energy efficiency by appropriate replacement of an automotive consumable part, provide a replacement-time position identification system of a consumable part and a replacement-time position identification method of a consumable part capable of continuously acquiring information relating to a vehicle of a customer, even for a customer who has defected from the dealership.

In order to achieve the above object, the present invention provides a replacement-time position identification system of consumable parts comprising: a consumable part consumption degree grasper (for example, an internal resistance value acquirer 101) that grasps an internal resistance value of a consumable part (for example, a battery described later) included in a movable body (for example, vehicles 200-1 to 200-n described later); a position acquirer (for example, position acquirer 102 described later) that acquires a travel position status in response to an ignition of the movable body being turned on or off; a data receiver (for example, a date receiver 105 described later) that receives data from the consumable part consumption degree grasper and data from the position acquirer; and a replacement-time position acquirer (for example, a replacement-time position acquirer 111 described later) that, based on a travel status of the movable body, identifies a position of the movable body as a replacement position of the consumable part, when a value of data of the internal resistance value from the consumable part consumption degree grasper satisfies a predetermined requirement in change.

Further, the present invention provides a replacement-time position identification method of consumable parts comprising: grasping an internal resistance value of a consumable part included in a movable body (for example, vehicles 200-1 to 200-n described later) (for example, step S101 described later); acquiring a travel position status in response to an ignition of the movable body being turned on or off (for example, step S101 described later); receiving data of the internal resistance value and data of the travel position status (for example, step S104 described later); and identifying, based on a travel status of the movable body, a position of the movable body as a replacement position of the consumable part, when a value of data of the internal resistance value from the consumable part consumption degree grasper satisfies a predetermined requirement in change (for example, step S105 described later).

Further, the consumable part is a battery, and the system identifies a replacement day based on a change in the internal resistance value of the battery. Further, the identifying further includes identifying a replacement day based on a change in the internal resistance value of the battery.

Further, the data receiver includes general map information and a replacement place register in which places where replacement of the consumable part is possible are registered in advance. Further, in the receiving the data, general map information and a replacement place register in which places where replacement of the consumable part is possible are registered in advance are available.

Further, the system further includes a replacement place identifier (for example, a replacement place identifier 107 described later) that identifies a place where the consumable part has been actually replaced by using information relating to the places registered in the replacement place register. Further, the identifying further includes identifying a place where the consumable part has been actually replaced by using information in which places where replacement of the consumable part is possible are registered in advance.

Further, the system further includes a place register (for example, a place register 108 described later) that registers a plurality of places where at least one selected from sales, maintenance, and management of the movable body is performed, and the place register registers a place where replacement of the consumable part is possible. Further, the method further includes registering a plurality of places where at least one selected from sales, maintenance, and management of the movable body is performed, and the registering the plurality of places further includes registering places where replacement of the consumable part is possible.

According to the present invention, it is possible to provide a replacement-time position identification system of a consumable part and a replacement-time position identification method of a consumable part capable of continuously acquiring information relating to a vehicle of a customer who has defected from a dealership and left the dealership.

### BRIEF DESCRIPTION OF THE DRAWINGS

FIG. 1 is a diagram showing a system according to an embodiment of the present invention;

FIG. 2 is a flowchart showing processing in the system according to the embodiment of the present invention;

FIG. 3 is a flowchart showing processing of the detection of battery replacement in the system according to the embodiment of the present invention;

FIG. 4 is a graph showing a change in internal resistance values of a battery of a vehicle;

FIG. 5 illustrates average values of the change in internal resistance values of a battery of a vehicle on a daily basis;

FIG. 6 shows a search target day of the change in internal resistance value of a battery of a vehicle;

FIG. 7 illustrates the detection of time in a day when a battery is replaced on the search target day;

FIG. 8 illustrates a first requirement for detection of time in a day when the battery was replaced on the search target day;

FIG. 9 illustrate a second requirement for detection of time in a day when the battery was replaced on the search target day;

FIG. 10 is a diagram for explaining a positional relationship between a place where a battery of a vehicle was replaced and a vehicle dealership;

FIG. 11 is a diagram for explaining a positional relationship between a vehicle dealership and competitors and the like around the vehicle dealership;

FIG. 12 is a diagram showing vehicles for which a battery has been replaced at a vehicle dealership and the competitors and the like around the vehicle dealership and the dates for the battery replacement of the vehicles;

FIG. 13 is a diagram showing the rate of customer defection from vehicle dealerships for each area; and

FIG. 14 shows graphs, each showing the number of vehicles for which the battery has been replaced for each day of the week, at a vehicle dealership and competitors and the like around the vehicle dealership.

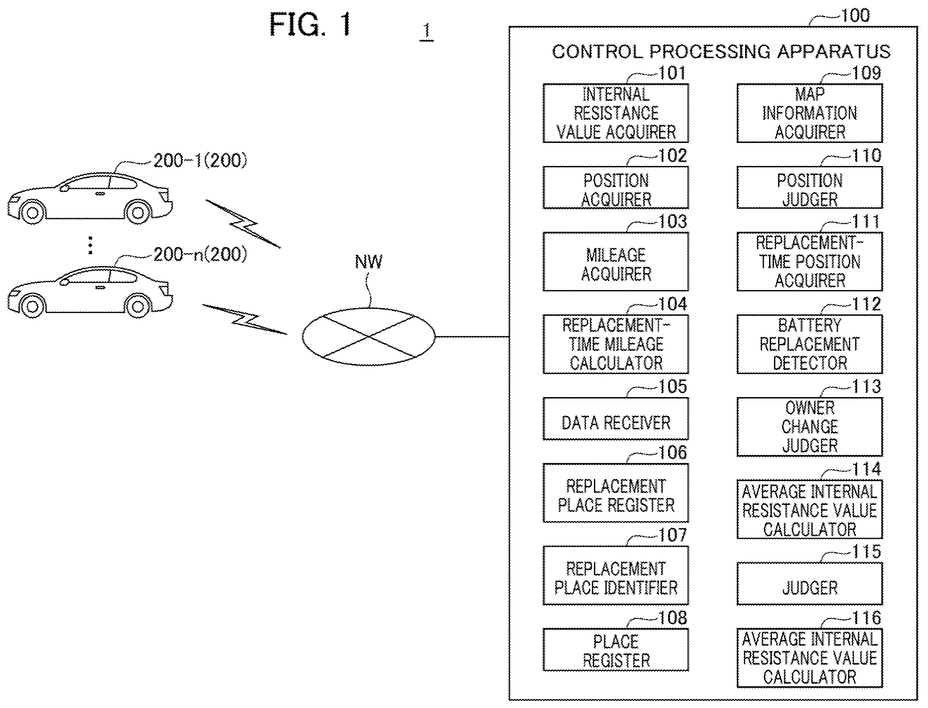

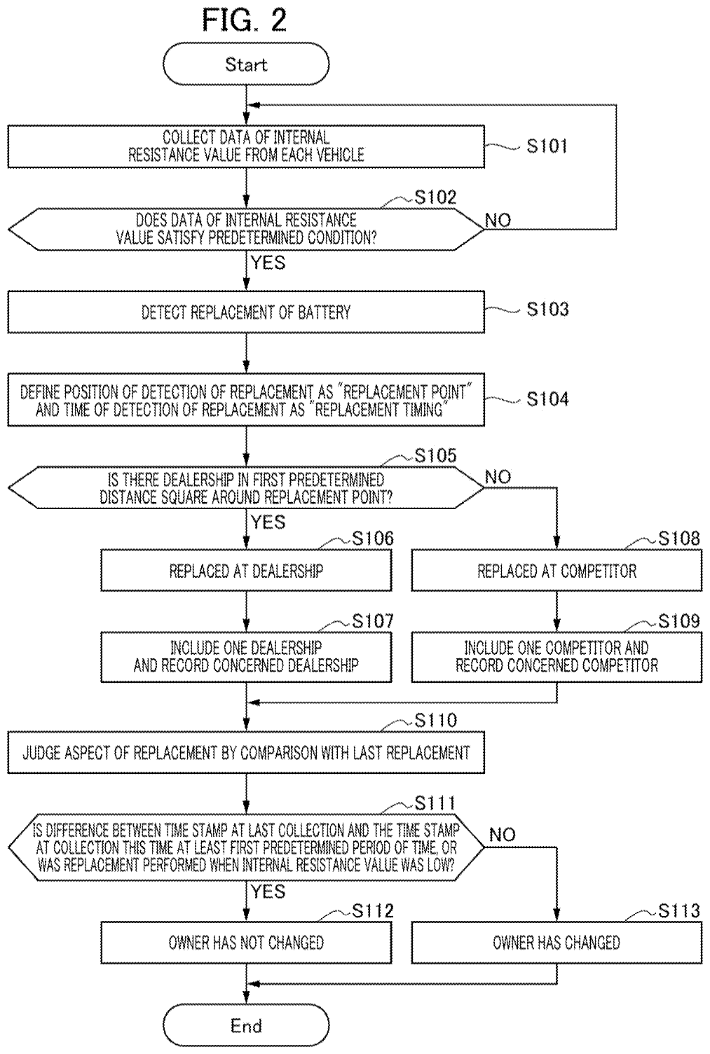

### DETAILED DESCRIPTION OF THE INVENTION

An embodiment of the present invention will be described below in detail with reference to drawings.

A system 1 of the embodiment is provided with a control processing apparatus 100 and vehicles 200-1 to 200-n (n is an integer satisfying n>1). The control processing apparatus 100 and each of the vehicles 200-1 to 200-n are mutually communicable via a network NW. The network NW includes the Internet, WAN (wide area network), LAN (local area network), a public line, a dedicated line and the like.

In the present embodiment, each of the vehicles 200-1 to 200-n is an engine vehicle that travels with an internal-combustion engine as a drive source or a hybrid vehicle that travels with an engine and a motor as drive sources. The vehicles 200-1 to 200-n are stopped in parking lots used by owners of the vehicles 200-1 to 200-n or at dealerships or competitors where a battery is replaced for the vehicles 200-1 to 200-n.

Each of the vehicles 200-1 to 200-n is a vehicle equipped with a wireless communication function, which is called a connected car. By the vehicles 200-1 to 200-n being connected to the network NW, pieces of vehicle data acquired from the vehicles 200-1 to 200-n are inputted to the control processing apparatus 100 via the network NW, and various analyses about the vehicles 200-1 to 200-n are carried out. The pieces of vehicle data include, for example, the places, mileages, internal resistance values of the battery and the like of the vehicles 200-1 to 200-n at the time of the ignitions of the vehicles 200-1 to 200-n being turned on, respectively. In the description below, the vehicles 200-1 to 200-n will be appropriately referred to as the vehicles 200.

The control processing apparatus 100 is realized by an apparatus such as a personal computer, a server or an industrial computer. The control processing apparatus 100 includes, for example, an internal resistance value acquirer 101, a position acquirer 102, a mileage acquirer 103, a replacement-time mileage calculator 104, a data receiver 105, a replacement place register 106, a replacement place identifier 107, a place register 108, a map information acquirer 109, a position judger 110, a replacement-time position acquirer 111, a battery replacement detector 112, an owner change judger 113, an average mileage calculator 114, a judger 115, and an average internal resistance value calculator 116. A consumable part replacement-time position identification system, a replacement time calculation system, a position judgment system and an owner change detection system are configured with the above components.

These systems are realized, for example, by a hardware processor such as a CPU (central processing unit) executing a program (software) stored in a storage unit (not shown). A part or all of these functional units may be realized by hardware (including circuitry) such as an LSI (large scale integration), an ASIC (application specific integrated circuit), an FPGA (field-programmable gate array) or a GPU (Graphics processing unit), or may be realized by cooperation between software and hardware.

The storage (not shown) in which the program is stored is realized by an HDD (hard disk drive), flash memory, RAM (random access memory), ROM (read-only memory) or the like. The program may be stored in a removable storage medium (non-transitory storage medium) such as a DVD or a CD-ROM, and installed by being fitted into a drive device. Further, in the storage unit, information about each vehicle 200, for example, information including the place, mileage, internal resistance value of the battery, and the like of the vehicle 200 at the time of the ignition of the vehicle 200 being turned on is stored.

The internal resistance value acquirer 101 grasps the internal resistance value of a battery as a consumable part of each vehicle 200, which is included in the vehicle data of the vehicle 200 acquired via the network NW.

The position acquirer 102 acquires information about the position (values of the longitude and the latitude) of each vehicle 200, which is a travel position status at the time of the ignition being turned on in the vehicle 200, the information being included in the vehicle data acquired from the vehicle 200. When the ignition is turned on after a battery is replaced in each vehicle 200, in a case in which an average value of the internal resistance values of the battery on a daily basis obtained by the average internal resistance value calculator 116 calculating the internal resistance values of the battery outputted from the internal resistance value acquirer 101 satisfies a predetermined requirement in change described later, the battery replacement detector 112 detects that battery replacement has been performed, and the replacement-time position acquirer 111 identifies the position of each vehicle 200 as an battery replacement position.

The mileage acquirer 103 acquires mileage of each vehicle 200 at the time of the ignition being turned on in the vehicle 200, the mileage being included in the vehicle data acquired from the vehicle 200.

The replacement-time mileage calculator 104 divides total mileage, which is mileage traveled by each vehicle 200, outputted from the mileage acquirer 103, by the number of times of battery replacement based on the change in the internal resistance values of the battery in each vehicle 200 outputted from the internal resistance value acquirer 101. With such a configuration, the replacement-time mileage calculator 104 calculates a time to replace battery.

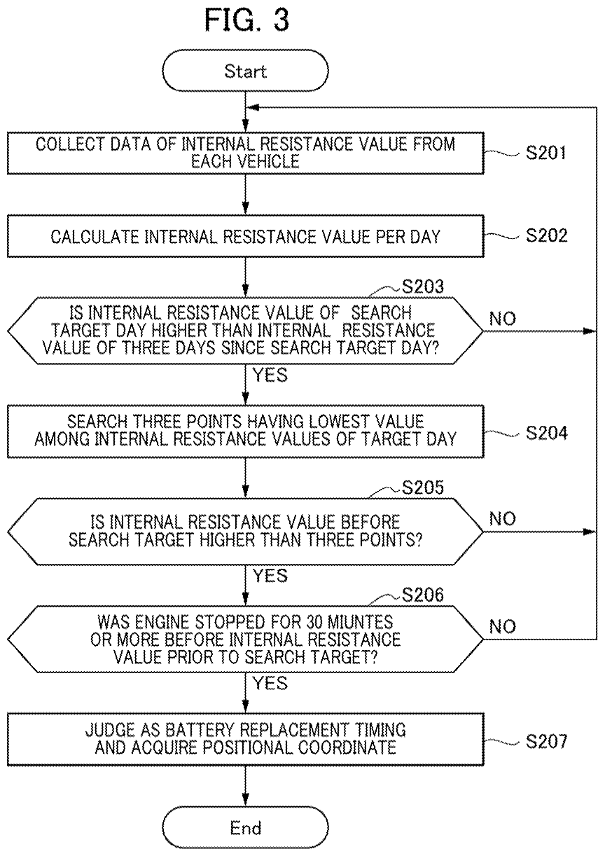

Specifically, the replacement-time mileage calculator 104 acquires the total mileage, which is mileage traveled by each vehicle 200. Further, the replacement-time mileage calculator 104 acquires an average value of mileage traveled between battery replacement and the next battery replacement, from the average mileage calculator 114. Here, the average mileage calculator 114 calculates an average value of mileage of each vehicle 200 from two adjacent replacements of the battery based on the change in the internal resistance value of the battery in each vehicle 200 outputted from the internal resistance value acquirer 101. As the mileage, a value outputted from the mileage acquirer 103 is used. Further, the replacement-time mileage calculator 104 determines average mileage per day of each vehicle 200 by dividing the total mileage by the number of days of use of the vehicle 200. Further, as shown in FIG. 3, the replacement-time mileage calculator 104 determines the most recent mileage traveled by each vehicle 200 after the battery was replaced most recently by subtracting recent mileage at the time of battery replacement based on the change in the internal resistance value of the battery from the total mileage of the vehicle 200. Then, the replacement-time mileage calculator 104 determines mileage remaining until the time when the battery is expected to be replaced next time from the current total mileage by subtracting the value of the most recent mileage from the average value of mileage of the vehicle 200 outputted from the average mileage calculator 114. Then, the replacement-time mileage calculator 104 divides the remaining mileage by the average mileage per day to determine the number of days remaining until the time when the battery is expected to be replaced.

The data receiver 105 receives data of the internal resistance value of the battery from the internal resistance value acquirer 101, data of mileage of each vehicle 200 at the time of the ignition being turned on in the vehicle 200, from the position acquirer 102, and data of mileage of each vehicle 200 at the time of the ignition being turned on in the vehicle 200, which is included in the vehicle data acquired from the vehicle 200, from the mileage acquirer 103.

Further, the data receiver 105 is provided with a map information acquirer 109 provided with general map information including ordinary map information such as transportation means, buildings and geographical features, and a replacement place register 106 with which places where a battery can be replaced are registered in advance. The general map information and the places are stored in a storage medium (not shown).

Further, the data receiver 105 is provided with the owner change judger 113. The owner change judger 113 judges whether the owner of each vehicle 200 has changed or not by comparing the internal resistance value of the battery and the date, and the position of the vehicle 200 at the time of the battery being replaced last time with the internal resistance value of the battery and the date, and the position of the vehicle 200 at the time of the battery being replaced this time.

More specifically, the owner change judger 113 detects that the owner of the vehicle 200 has not changed subject to a requirement being satisfied that battery replacement positions are the same, and time between the battery replacement last time and the battery replacement this time is longer than a first predetermine time in the above comparison. Here, as the first predetermined time, for example, the number of days smaller than half of the number of days corresponding to the average value of mileage outputted from the average mileage calculator 114 can be used. If the requirement is not satisfied, it means that the owner of the vehicle 200 changed and, even though not many days had passed after battery replacement by the previous owner, battery replacement was performed to sell the vehicle 200 as a used car. In FIG. 5, although the horizontal axis indicates mileage of the vehicle 200, dates and time are also shown along the horizontal axis.

Further, the owner change judger 113 detects that the owner of the vehicle 200 has not changed subject to a requirement being satisfied that a difference between the time stamp of the ignition being turned on immediately before battery replacement and the time stamp of the ignition being turned on immediately after the battery replacement is less than a second predetermined time in the above comparison. As the second predetermined time, for example, a week or the like can be used. If the requirement is not satisfied, it means that the owner of the vehicle 200 has changed, and the vehicle 200 has been in a state of being sold as a used car after battery replacement or the like.

The replacement place identifier 107 identifies a place where battery has actually been replaced, using information about the places registered with the replacement place register 106. Specifically, first, the sameness between the values of positions of the places registered with the replacement place register 106 and the value of a position when the position has been identified by the replacement place identifier 107 is judged by a judger 115.

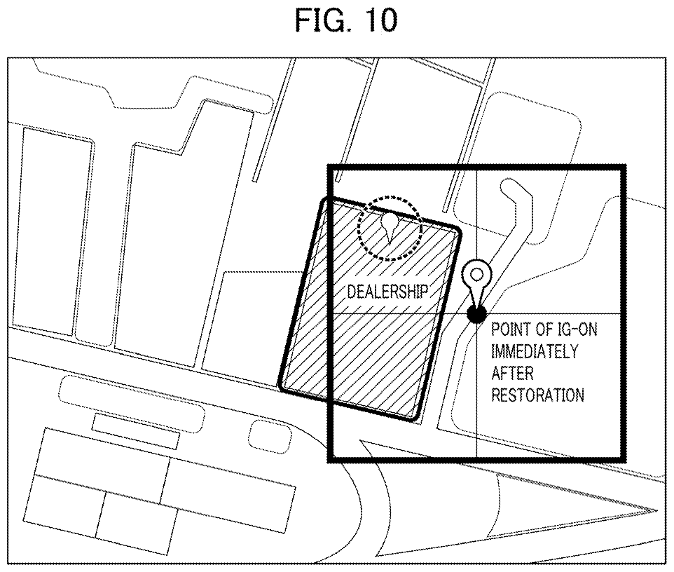

Next, from information about the position of the place of each vehicle 200 from the position acquirer 102, the replacement place identifier 107 judges whether or not there is a dealership or the like registered with the replacement place register 106, for example, in a range of a first predetermined distance square (a range surrounded by a square in FIG. 10) around the position of a place indicated by a black point where a pin stands in FIG. 10. Here, the first predetermined distance is a distance within which a building of a dealership registered with the replacement place register 106 as the dealership of the vehicle 200, where battery is replaced, is included. If it is judged that there is a dealership in the first predetermined distance square around a replacement point as shown in FIG. 10, the replacement place identifier 107 identifies the dealership as a place where the battery has actually been replaced. Then, the judger 115 judges whether the value of the position of any of the places registered with the replacement place register 106 and the value of a position identified by the replacement place identifier 107 in the case of the position being identified by the replacement place identifier 107 are the same or not. If the judger 115 judges that the values are the same, the place registered with the replacement place register 106 is registered as a place where the battery has actually been replaced.

If there is no registered place corresponding to the identified place, the position judger 110 compares the position of the place of the vehicle 200 with positions of places of competitors and the like included in the general map information of the map information acquirer 109 to judge an accurate position of the vehicle 200. Then, the map information acquirer 109 adds the judged accurate position to the general map information of the map information acquirer 109 as a new battery replacement place of the vehicle 200 from the position acquirer 102 and updates the general map information. The place register 108 registers the place with the replacement place register 106 as a competitor that performs at least one selected from sales, maintenance and management of the vehicle 200.

Next, a consumable part replacement-time position identification method implemented by control of the control processing apparatus 100 will be described. First, at step S101, the internal resistance value acquirer 101 of the control processing apparatus 100 collects the internal resistance value of the battery from each vehicle 200. Then, the processing of the control processing apparatus 100 proceeds to step S102.

In step S102, the control processing apparatus 100 judges whether the internal resistance value of the battery which the data receiver 105 has received from the internal resistance value acquirer 101 has satisfied a predetermined requirement in change.

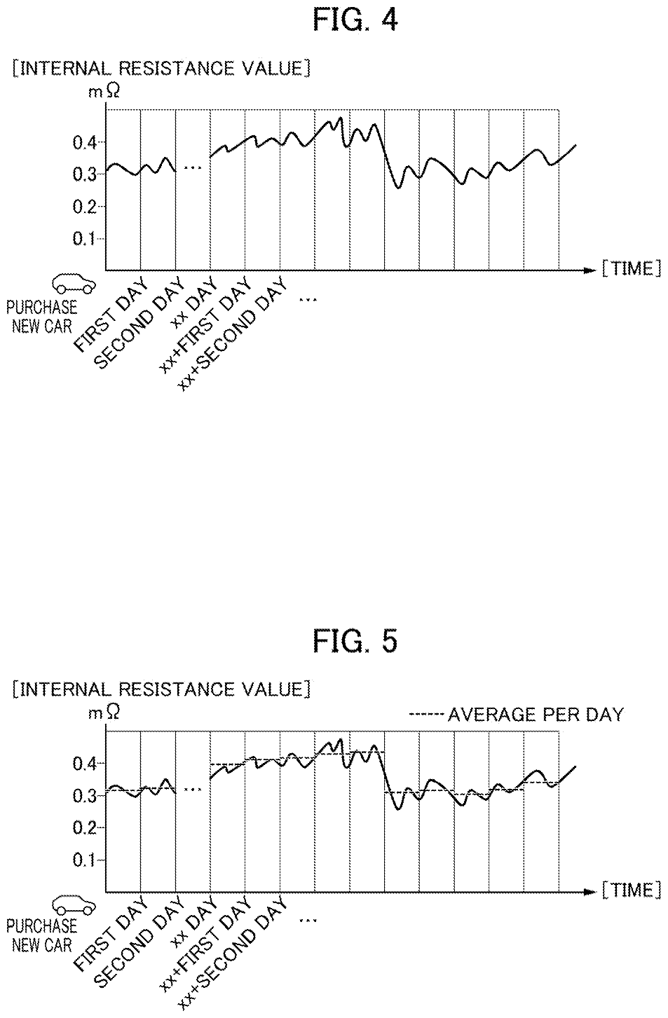

Specifically, as shown in FIG. 4, in step S201, the internal resistance value acquirer 101 collects the internal resistance value of the battery from each vehicle 200. Then, the processing of the control processing apparatus 100 proceeds to step S202.

In step S202, as shown in FIG. 5, the control processing apparatus 100 calculates the internal resistance value average value of the battery per day on a daily basis. Then, the processing of the control processing apparatus 100 proceeds to step S203.

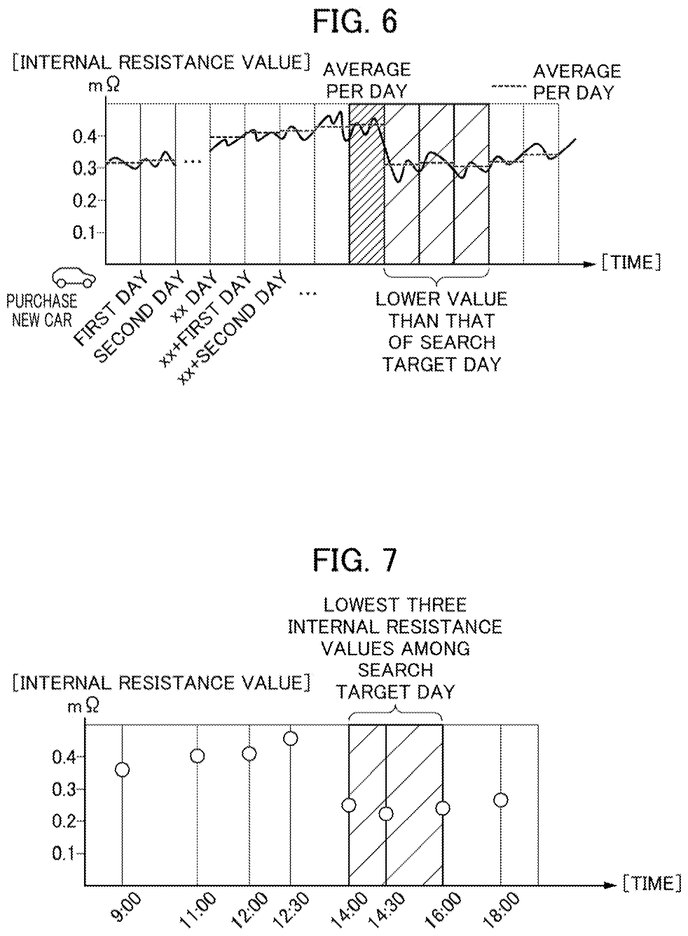

In step S203, as shown in FIG. 6, the control processing apparatus 100 judges whether there is a “search target day” on which the average value of the internal resistance value of the search target day takes a value higher than each of the average values of the internal resistance values of three days since the search target day. In a case where there is a “search target day” (step S203: YES), the processing of the control processing apparatus 100 proceeds to step S204. In a case where there is not a “search target day” (step S203: NO), the processing of the control processing apparatus 100 returns to step S201.

In step S204, as shown in FIG. 7, the control processing apparatus 100 searches three points which show the lowest values among the internal resistance values of the battery when the ignition is turned on in the “search target day”. The circles (o) in FIG. 7 each show the internal resistance value of the battery when the ignition is turned on. Then, the processing of the control processing apparatus 100 proceeds to step S205.

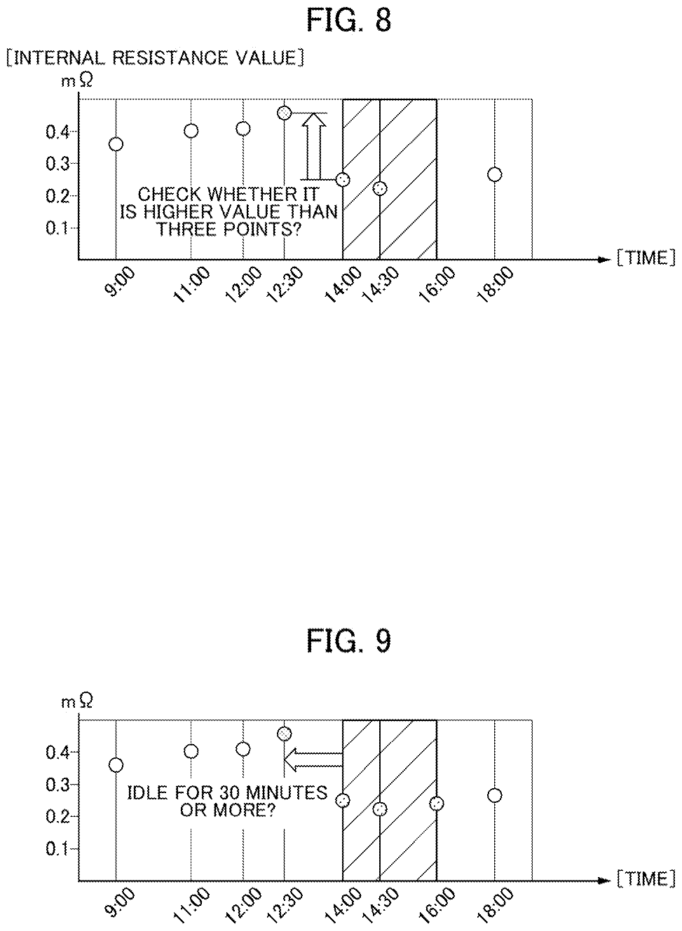

In step S205, as shown in FIG. 8, the control processing apparatus 100 judges whether the internal resistance value of the battery when the ignition is turned on immediately before the three points obtained in step S204 is higher than the three points. In a case where the internal resistance value thereof is higher than the three points (step S205: YES), the processing of the control processing apparatus 100 proceeds to step S206. In a case where the internal resistance value thereof is not higher than the three points (step S205: NO), the processing of the control processing apparatus 100 proceeds to step S201.

In step S206, as shown in FIG. 9, the control processing apparatus 100 judges whether the period of time from the time in a day when the ignition is turned on immediately before the three points obtained in step S204 until the earliest point of time among the three points is 30 minutes or more. In a case where the period of time is 30 minutes or more (step S206: YES), the processing of the control processing apparatus 100 proceeds to step S207. In a case where the period of time is less than 30 minutes (step S206: NO), the processing of the control processing apparatus 100 returns to step S201.

In step S207, the control processing apparatus 100 judges that the period of time between the three points obtained in step S204 and when the ignition is turned on immediately before the three points falls within the timing for battery replacement. Then, the control processing apparatus 100 acquires the positional coordinate of the vehicle and the date, and the time in a day in the period of time therebetween. Then, the processing of the control processing apparatus 100 proceeds to step S103.

In step S103, the battery replacement detector 112 of the control processing apparatus 100 detects that battery replacement has been performed, and the replacement-time position acquirer 111 identifies the position of the vehicle 200 where the battery replacement has been performed, as a battery replacement position. Then, the processing of the control processing apparatus 100 proceeds to step S104.

In step S104, the control processing apparatus 100 defines the position at which the battery replacement has been detected at the time of the ignition being turned on in the vehicle 200 and which has been received by the data receiver 105 from the position acquirer 102, as “a replacement point (a replacement position, a replacement place)”, and defines the time when the battery replacement has been detected as “a replacement timing (replacement time)”. The average mileage calculator 114 calculates the average value of mileage of the vehicle 200 for which battery replacement has been performed. By acquiring mileage of the vehicle 200 at the time of the ignition being turned on in the vehicle 200, from the mileage acquirer 103, the replacement-time mileage calculator 104 determines the number of days remaining until the time when the battery is expected to be replaced next time. Then, the date when the battery is expected to be replaced next time is stored into a storage medium not shown. Then, the processing of the control processing apparatus 100 proceeds to step S105.

In step S105, a battery replacement place is identified by the replacement place identifier 107 of the control processing apparatus 100, and the judger 115 of the control processing apparatus 100 judges the sameness between the values of the positions of the places registered with the replacement place register 106 and the value of the position of the place in the case of the place being identified by the replacement place identifier 107. That is, if it is judged that there is a dealership in the first predetermined distance square around the battery replacement point (step S105: YES), the processing of the control processing apparatus 100 proceeds to step S106. If it is judged that the dealership does not exist in the first predetermined distance square around the battery replacement point (step S105: NO), the processing of the control processing apparatus 100 proceeds to step S108.

In step S106, the control processing apparatus 100 judges that the place where battery replacement has been performed is the dealership. Then, the processing of the control processing apparatus 100 proceeds to step S107. In step S107, the control processing apparatus 100 includes one piece of data to the effect that battery replacement has been performed for the vehicle 200 at the dealership, and records the dealership into the replacement place register 106. Then, the processing of the control processing apparatus 100 proceeds to step S110.

In step S108, the control processing apparatus 100 judges that the place where battery replacement has been performed is not a dealership but rather a competitor. Then, the processing of the control processing apparatus 100 proceeds to step S109. In step S109, the control processing apparatus 100 includes one piece of data to the effect that battery replacement has been performed for the vehicle 200 at the competitor, and registers the competitor into the replacement place register 106. Then, the map information acquirer 109 adds an accurate position judged by the position judger 110 to the general map information of the map information acquirer 109 as a new battery replacement place, based on the position of each vehicle 200 from the position acquirer 102 and updates the general map information.

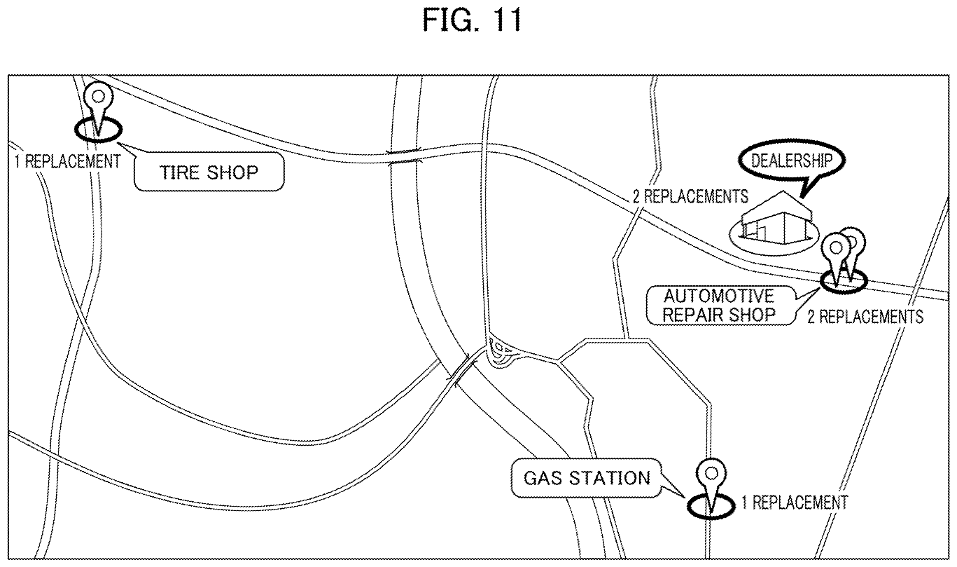

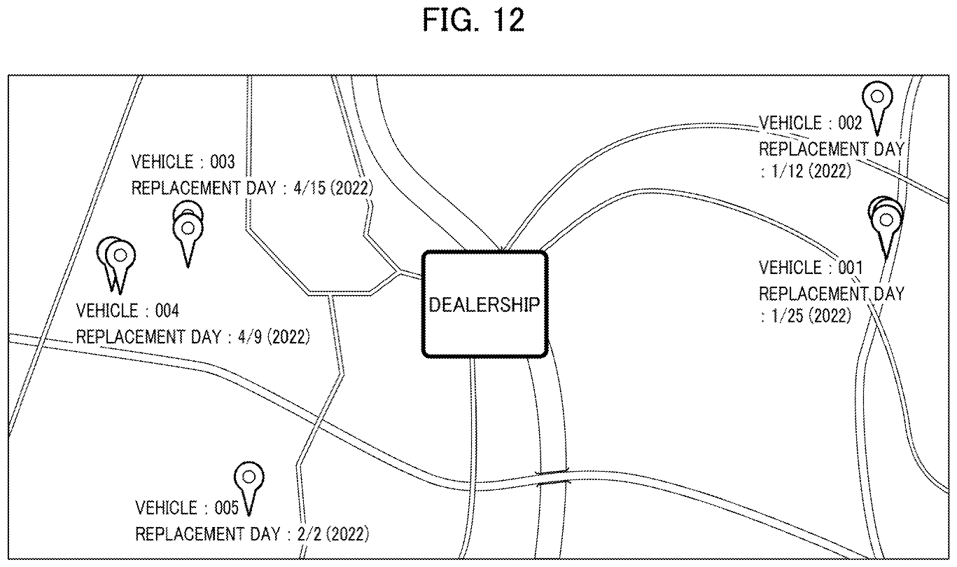

Specifically, as shown in FIG. 11, the number of battery replacements performed at competitors such as an automotive repair shop, a tire shop and a gas station are registered so as to be displayed on a map together with the dealership. Further, for example, as shown in FIG. 12, vehicle numbers of the vehicles 200 (for example, “Vehicle: 001” and the like), and the predicted date for replacing battery (for example, Jan. 25, 2022) in the vehicles 200 next time are recorded so that they can be displayed on the map. Then, the processing of the control processing apparatus 100 proceeds to step S110. As for display on the map, in addition to the above, the number of days until the battery is to be replaced in the vehicles 200 next time (for example, “Number of days remaining until replacement: 25 days” and the like) may be recorded.

In step S110, the control processing apparatus 100 compares a place where the battery was replaced for the vehicle 200 last time and the place where battery was replaced this time. Table 1 shows a specific example.

TABLE 1

| | | LAST TIME | | |
|---|---|---|---|---|
| | | | | SELF |
| | | DEALERSHIP | COMPETITOR | PROCUREMENT |
| THIS | DEALERSHIP | MANAGEMENT | CAPTURED | CAPTURED |
| TIME | | KEPT | | |
| | COMPETITOR | GOT OUT | CONTINUED | CONTINUED |
| | | THIS TIME | TO BE OUT | TO BE OUT |
| | SELF | GOT OUT | CONTINUED | CONTINUED |
| | PROCUREMENT | THIS TIME | TO BE OUT | TO BE OUT |

That is, if battery replacement was performed at a dealership last time, and battery replacement was also performed at a dealership this time, a status of “Management kept” indicating a state that management of the vehicle 200 by the dealer is continued is registered in the replacement place register 106. If battery replacement was performed at a dealership last time, but battery replacement was performed at a competitor or by the owner himself this time, a status of “Defected this time” indicating a state that the vehicle 200 defected from management by the dealer at the time of the battery replacement this time, is registered in the replacement place register 106. If battery replacement was performed at a competitor or by the owner himself last time, but battery replacement was performed at the dealership this time, a status of “Recaptured” indicating a state that management of the vehicle 200 by the dealer is to be performed again, is registered in the replacement place register 106. If battery replacement was performed at a competitor or by the owner himself last time, and battery replacement was also performed at a competitor or by the owner himself this time, a status of “Continued defecting” indicating a state that the vehicle 200 is still defected from the management by the dealer, is registered in the replacement place register 106. Then, the processing of the control processing apparatus 100 proceeds to step S111.

In step S111, the owner change judger 113 of the control processing apparatus 100 judges whether the replacement was performed after elapse of the first predetermined time during which the decrease in battery is small or whether a difference between the time stamp at the collection last time and the time stamp at the collection this time is less than the second predetermined time.

That is, in the above comparison, the owner change judger 113 judges whether or not the battery replacement positions (replacement places) are the same, and time between the battery replacement last time and the battery replacement this time is longer than the first predetermined time. Further, the owner change judger 113 judges whether or not a difference between the time stamp at the time of the ignition being turned on before the battery replacement and the time stamp at the time of the ignition being turned on immediately after the battery replacement is less than the second predetermined time.

If the results are positive in any of the judgments (S111: YES), the processing of the control processing apparatus 100 proceeds to step S112. If the results are negative in any of the judgments (S111: NO), the processing of the control processing apparatus 100 proceeds to step S113.

In step S112, the owner change judger 113 of the control processing apparatus 100 records that the owner has not changed, in a recording medium not shown. Then, the process of the control processing apparatus 100 ends.

In step S113, the owner change judger 113 of the control processing apparatus 100 records that the owner has changed, in the recording medium not shown. Then, the process of the control processing apparatus 100 ends.

According to the present embodiment, the following advantageous effects are obtained. In the present embodiment, the internal resistance value indicating a consumption status of battery as a consumable part of each vehicle 200 is grasped; a position as a travel position status is acquired in response to the ignition of the vehicle 200 being turned on; and data of the internal resistance value of the battery and data of the position are received. Then, based on the travel status of the vehicle 200, the position of the vehicle 200 is identified if the value of the data of the internal resistance value of the battery satisfies a predetermined requirement in change.

With such a configuration, if the value of the data of the internal resistance value of the battery satisfies a predetermined requirement in change, it becomes possible to identify the position of a place where the requirement is satisfied. Therefore, by regarding the position of the place where the requirement is satisfied as the position of a battery replacement place, it is possible to identify the replacement day when the battery was replaced and grasp an accurate market share. Further, it becomes possible to know competitors where battery replacement is performed and understand customer sentiment; it becomes possible to recapture customers who have left, by an optimal approach; and moreover, it becomes possible to improve the parts business income of the manufacturer of the vehicles 200.

Further, in the present embodiment, in the process for identifying the position of each vehicle 200, the data receiver 105 can use general map information and information with which places where the battery can be replaced are registered. With such a configuration, it becomes possible to identify a position where the battery has actually been replaced for each vehicle 200 on the general map information, comparing the position with the general map information.

Further, in the present embodiment, in the process for identifying the position of each vehicle 200, the replacement place identifier 107 identifies a place where the battery was actually replaced, from the information with which the places where the battery can be replaced are registered. With such a configuration, it becomes possible to grasp whether or not the battery replacement has been performed, at any of the already registered places where battery can be replaced.

Further, in the present embodiment, the judger 115 judges the sameness between the values of the information with which the places where battery can be replaced are registered and the value of information about the place where the battery has actually been replaced. With such a configuration, it becomes possible to grasp whether or not battery replacement has been performed at an already registered place where the battery can be replaced.

Further, in the present embodiment, mileage is acquired in response to the ignition of each vehicle 200 being turned on; the internal resistance value of the battery provided in the vehicle 200 is grasped; if the value of data of the internal resistance value of the battery satisfies a predetermined requirement in change, an average value of mileage between two adjacent values that satisfies the predetermined requirement in change is calculated; and time to replace battery is calculated by dividing total mileage traveled by the vehicle 200 by the number of times of the value of the data of the internal resistance values of the battery satisfies the predetermined requirement in change.

With such a configuration, it becomes possible to, not only in the case of the vehicle 200 being in the management kept status, but also in the case of changing to the defection status and in the case of the owner himself having performed battery replacement, grasp the internal resistance value of the battery, grasp battery replacement records and calculate the time to replace battery next time. Therefore, it is possible to predict the next replacement time for all the vehicles 200 including vehicles 200 that have defected, for which, conventionally, the time to replace battery next time could not be grasped. As a result, it becomes possible to find potential customers who are at an optimal timing of battery replacement around shops of the dealer and competitors or the like, and it becomes possible to realize increased sales of batteries as a part, by developing an efficient sales promotion approach. Further, by detection of a position in response to the ignition of each vehicle 200 being turned on, it becomes possible to grasp the customer's living area.

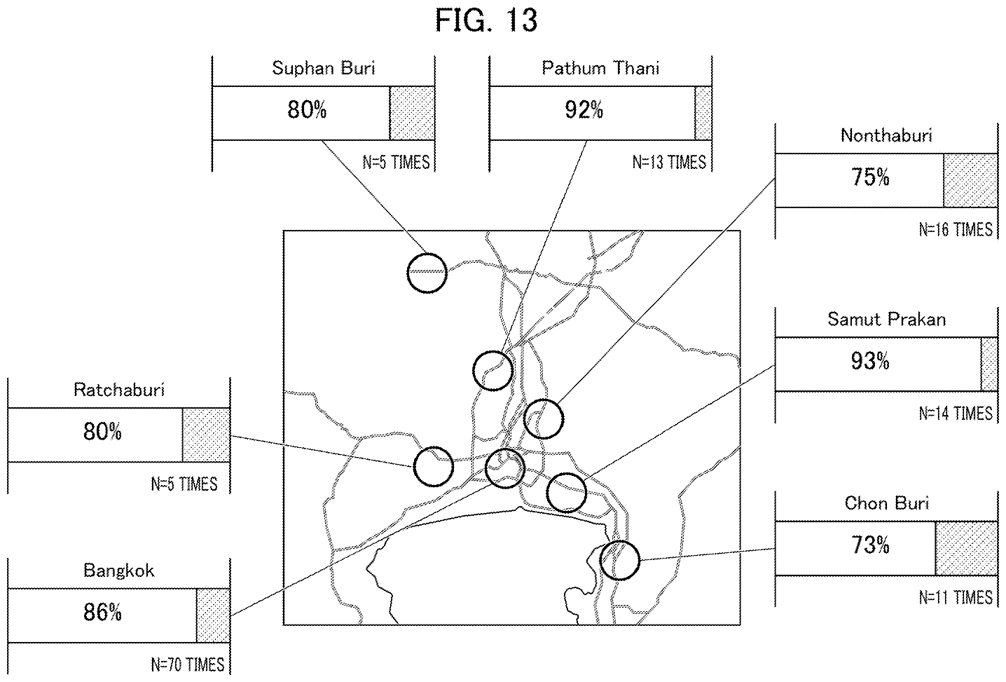

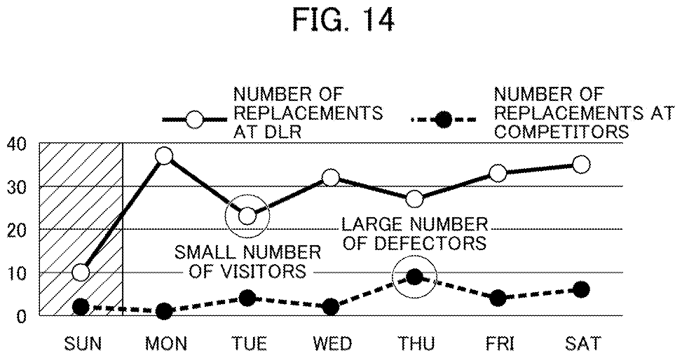

More specifically, for example, as shown in FIG. 13, it becomes possible to obtain the defection rate of customers of vehicles 200 in each city. A shaded part on the right side of the graph for each city in FIG. 13 indicates the defection rate. Further, it becomes possible to grasp the day of the week when battery replacement was performed. Therefore, for example, as shown in FIG. 14 it becomes possible to classify whether a place where battery replacement was performed is a dealership of the dealer of the vehicles 200 or a competitor, for each day of the week, and make the classification clear on graphs. With such a configuration, it becomes possible to make it clear that defection occurs on Tuesdays and Thursdays, which are often set as regular holidays of dealerships.

In the present embodiment, the position acquirer 102 acquires the position of each vehicle 200 for which battery replacement has been performed. With such a configuration, it becomes possible to grasp the position of the vehicle 200 for which battery replacement has been performed.

Further, in the present embodiment, the data receiver 105 receives data of mileage of each vehicle 200, data of the internal resistance value of the battery, and data of the position of the vehicle 200 at the time of battery replacement. With such a configuration, it becomes possible to highly accurately calculate the time to replace battery next time, using the above data.

Further, in the present embodiment, in the process for receiving data by the data receiver 105, it is possible to use general map information and information with which places where the battery can be replaced are registered. With such a configuration, it becomes possible to identify the position of a dealership or the like where the battery has actually been replaced for each vehicle 200, on the general map information, comparing the position with the general map information. As a result, it becomes possible to highly accurately calculate the time to replace battery next time based on the position and mileage of the vehicle 200. Further, it is possible to, for each customer, plot mileage of the vehicle of the customer remaining until the next battery replacement on the general map information and register the mileage. Furthermore, it becomes possible to, based on the general map information, calculate a more accurate time to replace battery and mileage remaining until the replacement in consideration of the customer's driving characteristics about accelerator operations, brake operations and the like and geographical features in the customer's living area.

Further, in the present embodiment, the position of each vehicle 200 as a travel position status is acquired in response to the ignition of the vehicle 200 being turned on; a plurality of places where at least one selected from sales, maintenance and management of the vehicles 200 is performed are registered; and if an acquired position of the vehicle 200 is different from the registered places, an accurate position is judged by comparison with the general map information. With such a configuration, it is possible to reflect accurate position information on a map based on the registered places, and it becomes possible to efficiently grasp map data and the needs of the customers of the vehicles 200.

Further, in the present embodiment, in the process for judging an accurate position, the map information acquirer 109 adds a place judged by the judger 115 to the general map information and updates the general map information. With such a configuration, it becomes possible to accurately register a place where battery replacement has actually been performed with the general map information.

Further, in the present embodiment, the replacement-time position acquirer 111 acquires the position of each vehicle 200 at the time of battery replacement. With such a configuration, it becomes possible to grasp the position of the vehicle 200 at the time of battery replacement, and it becomes possible to grasp whether the position corresponds to the dealership of the vehicle 200 or a competitor.

Further, in the present embodiment, in the process for registering a plurality of places, the place register 108 registers places where the battery can be replaced. With such a configuration, it becomes possible to grasp the number of times of and the time to perform battery replacement at the registered places where the battery can be replaced, and it becomes possible to grasp the actual situation of defection of the customers of the vehicles 200, which conventionally has not been seen, in detail for each area. As a result, it becomes possible to develop a customer recapture approach corresponding to the actual situation of each area and lead to increased sales of battery as parts of the vehicles 200.

Further, in the present embodiment, the internal resistance value of the battery of each vehicle 200 is grasped; a position as a travel position status is acquired in response to the ignition of the vehicle 200 being turned on; replacement of the battery as a consumable part is detected according to a travel status of the vehicle 200; data of the internal resistance value of the battery and data of the position are received; and it is judged whether the owner of the vehicle 200 has changed or not by comparing the internal resistance value of the battery and the position of the vehicle 200 at the time of replacing battery last time with the internal resistance value of the battery and the position of the vehicle 200 at the time of replacing battery this time.

With such a configuration, it becomes possible to, by detecting battery replacement, grasp owner change, which conventionally has not been seen, for each vehicle 200. Therefore, it becomes possible to prevent losses and decrease in CSI (customer satisfaction index) due to continuous sales promotion activities for old owners, and it becomes possible to lead to expansion of new development by new sales promotion activities for new owners.

Further, in the present embodiment, in the process for receiving data of the internal resistance value of the battery and data of a position, general map information can be used. With such a configuration, it becomes possible to identify a place where the owner has changed on the general map information.

Further, in the present embodiment, in the process for receiving data of the internal resistance value of the battery and data of a position, information with which places where the battery can be replaced are registered can be used. With such a configuration, it becomes possible to grasp a relationship between a place where the owner has changed and a place where the battery can be replaced.

Further, in the present embodiment, in the process for judging whether the owner has changed or not, the owner change judger 113 detects that the owner of each vehicle 200 has changed subject to a requirement being satisfied that battery replacement positions are the same, and the time between battery replacement last time and battery replacement this time is shorter than a predetermine time. With such a configuration, it is possible to easily judge whether the owner has changed or not.

The present invention is not limited to the above embodiment, and modifications, improvements and the like within a range that the object of the present invention can be achieved are included in the invention. For example, though the movable body is a vehicle 200, and the consumable part is battery in the present embodiment, the present invention is not limited thereto. For example, the movable body may be any vehicles in general that are mounted with an engine and use a battery.

Further, in the present embodiment, in step S203, the control processing apparatus 100 judges whether there is a “search target day” in which the average value of the internal resistance value thereof is higher than each of the average values of the internal resistance values of three days after the search target day, as shown in FIG. 6. However, the present invention is not limited thereto. “Three days” is merely an example and, for example, five days other than three days may be available depending on a country, a region, etc., where a vehicle is used.

Similarly, in the present embodiment, in step S205, as shown in FIG. 8, the control processing apparatus 100 judges whether the internal resistance value of the battery when the ignition is turned on immediately before the three points obtained in step S204 is higher than the three points. However, the present invention is not limited thereto. “Three points” is merely an example and, for example, may be five points other than three points depending on a country, a region, etc., where a vehicle is used.

Further, although the position acquirer 102 acquires information about the position of each vehicle 200, which is a travel position status at the time of the ignition being turned on in the vehicle 200 in the present embodiment, the present invention is not limited thereto. For example, the position acquirer 102 may acquire information about the position of each vehicle 200, which is a travel position status at the time of the ignition being turned off in the vehicle 200. In this case, the mileage acquirer 103 can acquire the mileage of each vehicle 200 at the time of the ignition being turned off in the vehicle 200, which is included in the vehicle data acquired from the vehicle 200. Further, the data receiver 105 can receive data of mileage of each vehicle 200 at the time of the ignition being turned on in the vehicle 200, from the position acquirer 102, and data of mileage of the vehicle 200 at the time of the ignition being turned off in the vehicle 200, from the mileage acquirer 103, which is included in the vehicle data acquired from the vehicle 200. Further, the owner change judger 113 can detect whether the owner of each vehicle 200 has changed or not based on a difference time between the time stamp at the time of the ignition being turned off and the time stamp of the ignition being turned off next.

Further, although the replacement-time mileage calculator 104 determines a date when the value of the internal resistance value of the battery next time is expected to satisfy a predetermined requirement in change, that is, a date when battery is predicted to be replaced next time in the present embodiment, the present invention is not limited to this configuration. For example, the replacement-time mileage calculator 104 may determine only mileage remaining until the internal resistance value next time satisfies a predetermined requirement in change, that is, until the time when battery is predicted to be replaced next time, without determining a date.

Further, in addition to the configuration of the present embodiment, such a configuration may also be provided that, in order to efficiently perform inspection and replacement of a consumable part, utilizes a sensor to urge the inspection and replacement.

Further, the replacement-time mileage calculator 104 may be adapted to derive a more accurate expected replacement date, taking into account the driving characteristics (about acceleration and braking) of a vehicle customer, in addition to the configuration of the present embodiment.

### EXPLANATION OF REFERENCE NUMERALS

1 System
100 Control processing apparatus
101 Internal resistance value acquirer (consumable part consumption degree grasper)
102 Position acquirer
103 Mileage acquirer
104 Replacement-time mileage calculator
105 Data receiver
106 Replacement place register
107 Replacement place identifier
108 Place register
109 Map information acquirer
110 Position judger
111 Replacement-time position acquirer
112 Battery replacement detector (consumable part replacement detector)
113 Owner change judger
114 Average mileage calculator
115 Judger
116 Average internal resistance value calculator
200-1 to 200-n Vehicle

What is claimed is:

1. A replacement-time position identification system of consumable parts comprising:
a consumable part consumption degree grasper that grasps an internal resistance value of a consumable part included in a movable body;
a position acquirer that acquires a travel position status in response to an ignition of the movable body being turned on or off;
a data receiver that receives data from the consumable part consumption degree grasper and data from the position acquirer; and
a replacement-time position acquirer that, based on a travel status of the movable body, identifies a position of the movable body as a replacement position of the consumable part, when a value of data of the internal resistance value from the consumable part consumption degree grasper satisfies a predetermined requirement in change.

2. The replacement-time position identification system according to claim 1, wherein the consumable part is a battery, and the system identifies a replacement day based on a change in the internal resistance value of the battery.

3. The replacement-time position identification system according to claim 1, wherein the data receiver includes general map information and a replacement place register in which places where replacement of the consumable part is possible are registered in advance.

4. The replacement-time position identification system according to claim 3, further comprising a replacement place identifier that identifies a place where the consumable part has been actually replaced by using information relating to the places registered in the replacement place register.

5. The replacement-time position identification system according to claim 1, further comprising a place register that registers a plurality of places where at least one selected from sales, maintenance, and management of the movable body is performed,
wherein the place register registers a place where replacement of the consumable part is possible.

6. A replacement-time position identification method of consumable parts comprising:
grasping an internal resistance value of a consumable part included in a movable body;
acquiring a travel position status in response to an ignition of the movable body being turned on or off;
receiving data of the internal resistance value and data of the travel position status; and
identifying, based on a travel status of the movable body, a position of the movable body as a replacement position of the consumable part, when a value of data of the internal resistance value from the consumable part consumption degree grasper satisfies a predetermined requirement in change.

7. The replacement-time position identification method according to claim 6, wherein the consumable part is a battery, and the identifying further includes identifying a replacement day based on a change in the internal resistance value of the battery.

8. The replacement-time position identification method according to claim 6, wherein, in the receiving the data, general map information and a replacement place register in which places where replacement of the consumable part is possible are registered in advance are available.

9. The replacement-time position identification method according to claim 8, wherein the identifying further includes identifying a place where the consumable part has been actually replaced by using information in which places where replacement of the consumable part is possible are registered in advance.

10. The replacement-time position identification method according to claim 6, further comprising registering a plurality of places where at least one selected from sales, maintenance, and management of the movable body is performed,
wherein the registering the plurality of places further includes registering places where replacement of the consumable part is possible.
